(19) United States
(12) Patent Application Publication
(10) Pub. No.: US 2016/0032451 A1
(43) Pub. Date: Feb. 4, 2016

(54) REMOTE PLASMA CLEAN SOURCE FEED BETWEEN BACKING PLATE AND DIFFUSER

(71) Applicant: Applied Materials, Inc., Santa Clara, CA (US)

(72) Inventors: Shinichi KURITA, San Jose, CA (US); Robin L. TINER, Santa Cruz, CA (US); Suhail ANWAR, Saratoga, CA (US)

(21) Appl. No.: 14/446,098

(22) Filed: Jul. 29, 2014

(51) Int. Cl. C23C 16/44; B08B 7/00

(52) U.S. Cl. CPC C23C 16/4405; B08B 7/0035

(57) ABSTRACT

Embodiments of the present disclosure provide an apparatus having a remote plasma clean source in which the remote plasma clean source delivers radicals from the remotely generated plasma to the chamber at a location disposed between a backing plate and a diffuser.

### BACKGROUND

1. Field

Embodiments of the present disclosure generally relate to an apparatus having a remote plasma clean source coupled to the chamber such that the radicals from the plasma enter the chamber at a location disposed between the backing plate and the diffuser.

2. Description of the Related Art

Plasma enhanced chemical vapor deposition (PECVD) is generally employed to deposit thin films on substrates, such as semiconductor substrates, solar panel substrates, organic light emitting diode (OLED) substrates and liquid crystal display (LCD) substrates. PECVD is generally accomplished by introducing a precursor gas into a vacuum chamber having a substrate disposed on a substrate support.

Uniformity is generally desired in the thin films deposited using a PECVD process. For example, a silicon nitride film is usually deposited using PECVD on a flat panel for a passivation or gate dielectric layer in a thin film transistor (TFT). The quality and uniformity of the silicon nitride film are important for commercial operation.

Oftentimes, the chamber in which the PECVD occurs needs to be cleaned due to the buildup of silicon nitride on exposed chamber parts. To clean the chamber, plasma may be ignited in situ or, delivered to the chamber from a remote plasma clean source. The cleaning plasma may generate undesired particles in the chamber.

Therefore, there is a need in the art for apparatus that may be cleaned with minimal particle generation.

### SUMMARY

Embodiments of the present disclosure provide an apparatus having a remote plasma clean source in which the remote plasma clean source delivers radicals from the remotely generated plasma to the chamber at a location disposed between a backing plate and a diffuser.

In one embodiment, an apparatus comprises a chamber body; a gas distribution plate disposed in the chamber body; a backing plate disposed in the chamber body and spaced from the gas distribution plate; a blocker plate assembly disposed within chamber body between the gas distribution plate and the backing plate; and a remote plasma clean source coupled to the chamber body, wherein the remote plasma clean source has at least one outlet in the chamber body and wherein the at least one outlet is disposed between the gas distribution plate and the blocker plate assembly.

In another embodiment, an apparatus comprises a chamber body; a gas distribution plate disposed in the chamber body; a backing plate disposed in the chamber body and spaced from the gas distribution plate; a first blocker plate disposed between the gas distribution plate and the backing plate; a second blocker plate disposed between the first blocker plate and the backing plate; and a remote plasma clean source coupled to the chamber body, wherein the remote plasma clean source has at least one outlet in the chamber body and wherein the at least outlet is disposed between the first blocker plate and the second blocker plate.

In another embodiment, a method of cleaning a processing chamber comprises generating a plasma remote from the processing chamber; delivering radicals from the plasma to the processing chamber, wherein the radicals are delivered to the processing chamber at a location disposed between a gas distribution plate and a blocker plate; delivering an inert gas through a backing plate to the processing chamber; and flowing the radicals and inert gas through the gas distribution plate.

In another embodiment, a method of cleaning a processing chamber comprises generating a plasma remote from the processing chamber; delivering radicals from the plasma to the processing chamber, wherein the radicals are delivered to the processing chamber at a location disposed between a first blocker plate and a second blocker plate; delivering an inert gas through a backing plate to the processing chamber; and flowing the radicals and inert gas through a gas distribution plate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 schematically illustrates a sectional side view of a PECVD chamber in accordance with one embodiment of the present disclosure.

FIG. 2 is a schematic partial cross-sectional illustration of chamber showing a remote plasma clean source introducing radicals at locations between the backing plate and showerhead.

FIGS. 3A-3B are isometric illustrations of outlets from a remote plasma clean source according to one embodiment.

FIGS. 4A-4C are isometric illustrations of outlets from a remote plasma clean source according to another embodiment.

FIG. 5 is a schematic cross-sectional illustration of a blocker plate and showerhead according to one embodiment.

FIG. 6 is a sectional side view of a PECVD chamber according to another embodiment.

FIG. 7 is a flow chart illustrating the operation of a PECVD chamber.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments of the present disclosure provide an apparatus having a remote plasma clean source in which the remote plasma clean source delivers radicals from the remotely generated plasma to the chamber at a location disposed between a backing plate and a diffuser.

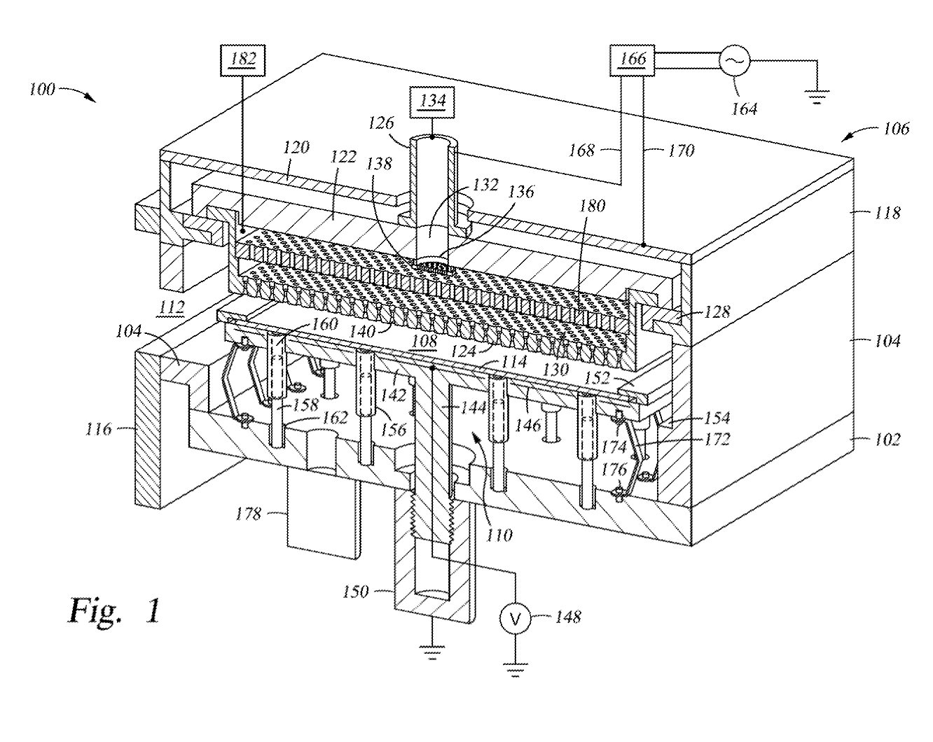

FIG. 1 schematically illustrates a sectional side view of an apparatus including a plasma processing chamber 100 in accordance with one embodiment of the present disclosure. The plasma processing chamber 100 comprises a chamber body having a chamber bottom 102, sidewalls 104, and a lid assembly 106. The chamber bottom 102, sidewalls 104, and the lid assembly 106 define a processing volume 108. A substrate support assembly 110 is disposed in the processing volume 108. An opening 112 is formed through one side of the sidewalls 104. The opening 112 is configured to allow passage of substrate 114. A slit valve 116 is coupled to the sidewall 104 and configured to close the opening 112 during processing.

The lid assembly 106 is supported by the sidewalls 104 and can be removed to service the interior of the plasma processing chamber 100. The lid assembly 106 comprises an outer lid 118, a lid cover plate 120, a backing plate 122, a gas distribution plate 124 (oftentimes referred to as a diffuser or a showerhead), a gas conduit 126, and an isolator 128.

The backing plate 122 and the gas distribution plate 124 are disposed substantially parallel to each other forming a gas distribution volume 130 therebetween. The backing plate 122 and gas distribution plate 124 are configured to distribute a processing gas to the processing volume 108. The backing plate 122 and the gas distribution plate 124 are typically fabricated from aluminum. The isolator 128 is disposed on the sidewalls 104 and configured to electrically isolate the side walls 104 from the gas distribution plate 124 and the backing plate 122. The lid cover plate 120 is supported by the outer lid 118, and electrically connected to the sidewalls 104.

A through hole 132 is formed through the backing plate 122. The through hole 132 connects the gas distribution volume 130 to a gas source 134 through a gas conduit. The gas source 134 is configured to provide one or more processing gases. The through hole 132 opens to the gas distribution volume 130 at an opening 136. A mini blocker plate assembly 138 is disposed over the opening 136. The mini blocker plate assembly 138 is configured to direct gas flow from the through hole 132 across the gas distribution volume 130 to enable processing gases substantially even distributed in the gas distribution volume 130 and eventually evenly distributed in the processing volume 108.

The gas distribution plate 124 has a perforated area substantially corresponding to a processing area of a substrate 114 disposed on the substrate support assembly 110. A plurality of holes 140 are formed through the gas distribution plate 124 and provide fluid communication between the gas distribution volume 130 and the processing volume 108. The perforated area of the gas distribution plate 124 is configured to provide a uniform distribution of gases passing through the gas distribution plate 124 into the processing volume 108.

In one embodiment, the gas distribution plate 124, the backing plate 122, the blocking plate assembly 180 and the mini blocker plate assembly 138 may be fabricated from metals or other comparably electrically conductive materials, for example, aluminum, stainless steel, or metal alloys.

The substrate support assembly 110 is centrally disposed within the processing volume 108 and supports the substrate 114 during processing. The substrate support assembly 110 generally comprises an electrically conductive support body 142 supported by a shaft 144 which extends through the chamber bottom 102. The support body 142 is generally polygonal in shape and covered with an electrically insulative coating over at least the portion of the support body 142 that supports the substrate 114. The insulative coating may also cover other portions of the support body 142. In one embodiment, the substrate support assembly 110 is normally coupled to a ground potential at least during processing.

The support body 142 may be fabricated from metals or other comparably electrically conductive materials, for example, aluminum. The insulative coating may be a dielectric material such as an oxide, silicon nitride, silicon dioxide, aluminum dioxide, tantalum pentoxide, silicon carbide or polyimide, among others, which may be applied by various deposition or coating processes, including, but not limited to, flame spraying, plasma spraying, high energy coating, chemical vapor deposition (CVD), spraying, adhesive film, sputtering and encapsulating.

In one embodiment, the support body 142 encapsulates at least one embedded heating element 146 configured to heat the substrate 114 during processing. In one embodiment, the support body 142 also comprises a thermocouple for temperature control. In one embodiment, the support body 142 may comprise one or more stiffening members comprised of metal, ceramic or other stiffening materials embedded therein.

The heating element 146, such as an electrode or resistive element, is coupled to a power source 148 and controllably heats the substrate support assembly 110 and substrate 114 positioned thereon to a predetermined temperature. Typically, the heating element 146 maintains the substrate 114 at a uniform temperature of about 150 to at least about 460 degrees Celsius during processing. The heating element 146 is electrically floating relative to the support body 142.

The shaft 144 extends from the support body 142 through the chamber bottom 102 and couples the substrate support assembly 110 to a lift system 150. The lift system 150 moves the substrate support assembly 110 between an elevated processing position and a lowered position that facilitates substrate transfer.

In one embodiment, the substrate support assembly 110 comprises a circumscribing shadow frame 152. The circumscribing shadow frame 152 is configured to prevent deposition or other processing on edges of the substrate 114 and the support body 142 during processing. The circumscribing shadow frame 152 rests on the substrate 114 and the support body 142 when the substrate support assembly 110 is in an elevated processing position. When the substrate support assembly 110 is in a lowered position for substrate transferring, the circumscribing shadow frame 152 rests above the substrate support assembly 110 on a step 154 formed on the sidewalls 104.

In one embodiment, the support body 142 has a plurality of pin holders 156 disposed therethrough and configured to direct a plurality of lifting pins 158. Each pin holder 156 has a through hole 160 formed therein. The through hole 160 opens to an upper surface of the support body 142. Each pin holder 156 is configured to receive one lifting pin 158 from a lower opening of the through hole 160. Each lifting pin 158 extends upward from a recess 162 formed in the chamber bottom 102. As the support body 142 lowers along with the plurality of pin holders 156, the plurality of lifting pins 158 poke through the through holes 160 and pick up the substrate 114. The substrate 114 is then separated from the support body 142 allowing a substrate handler to transfer the substrate 114 out of the plasma processing chamber 100.

An RF power source 164 is used to generate plasma in the processing volume 108. In one embodiment, an impedance matching circuit 166 is coupled to the RF power source 164. A first output 168 of the impedance matching circuit 166 is connected with the gas distribution plate 124, and a second output 170 of the impedance matching circuit 166 is connected with the substrate support assembly 110, thus, applying a RF power between the processing gas disposed between the gas distribution plate 124 and the substrate support assembly 110 and generating and sustaining a plasma for processing the substrate 114 on the substrate support assembly 110.

In one embodiment, the first output 168 of the impedance matching circuit 166 is connected with the gas distribution plate 124 via the gas conduit 126 and the backing plate 122. In one embodiment, the second output 170 is coupled to the chamber body, e.g. the sidewalls 104, or the lid cover plate 120.

In one embodiment, a plurality of RF returning straps 172 are connected between the support body 142 of the substrate support assembly 110 by a fastening mechanism 174 and to the chamber bottom 102 by a fastening mechanism 176 which is connected to the second output 170 of the impedance matching circuit 166. The plurality of RF returning straps 172 provide an RF current return path between the support body 142 and the chamber bottom 102. The chamber 100 is evacuated by a vacuum pump 178 that is coupled to the chamber 100.

A blocker plate assembly 180 is disposed between the backing plate 122 and the gas distribution plate 124. The blocker plate assembly 180 is used evenly distribution the processing gas behind the gas distribution plate 124. For chamber cleaning, a remote plasma clean source 182 is used to ignite a plasma remote from the chamber 100. Radicals from the remotely generated plasma are delivered to the chamber 100 through an inlet that is disposed between the gas distribution plate 124 and the backing plate 122. As will be discussed below, in one embodiment, the inlet is disposed between the gas distribution plate 124 and the blocker plate assembly 180.

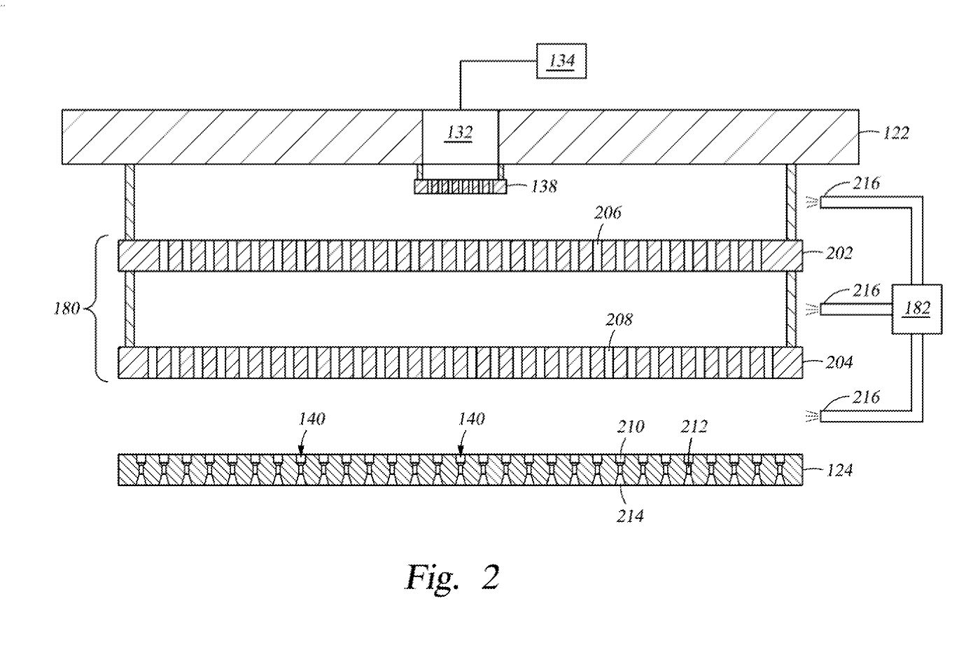

FIG. 2 is a schematic partial cross-sectional illustration of chamber showing the RPS 182 introducing radicals at locations between the backing plate 122 and showerhead 124. In the embodiment shown in FIG. 2, the blocker plate assembly 180 includes two blocker plates 202, 204 each having gas passages 206, 208 therethrough. Additionally, the gas passages 140 of the showerhead 124 are shown to have a top bore 210, a pinch point 212 and a hollow cathode cavity 214. The remote plasma clean source 182 generates a plasma for cleaning the chamber. The radicals generated from the plasma are delivered to the chamber at a location between the showerhead 124 and the backing plate 122. As shown in FIG. 2, outlets 216 for delivering the radicals may be disposed at one of three locations: between the showerhead 124 and the blocker plate assembly 180; between the blocker plate assembly 180 and the backing plate 122; and between blocker plates 202, 204 of the blocker plate assembly 180. It is to be understood that while two blocker plates 202, 204 have been shown, a single blocker plate 202 is contemplated as is a greater number (i.e., more than 2). The two blocker plates 202, 204 are shown as one contemplated embodiment.

It is believed that by introducing the radicals to the chamber at a location between the showerhead 124 and the backing plate 122, rather than through the through hole 132, particle generation may be reduced or even eliminated. When the radicals are delivered to the chamber through the through hole 132, the radicals pas through not only the backing plate 122, but additionally the mini blocker plate assembly 138, the blocker plate assembly 180 and the showerhead 124. Therefore, the residence time for the radicals within the area between the backing plate 122 and the showerhead 124 is considerably large. With an increase in residence time, the radicals may recombine and hence, be less effective in cleaning the chamber. Furthermore, the higher the residence time, the greater likelihood of the radicals reacting with the showerhead 124, backing plate 122, mini blocker plate assembly 138 and blocker plate assembly 180. The showerhead 124, backing plate 122, mini blocker plate assembly 138 and blocker plate assembly 180 may comprise aluminum or anodized aluminum. The cleaning radicals, specifically fluorine radicals, may react with the aluminum to produce aluminum fluoride particles that contaminate the chamber. By reducing the residence time, the fluorine may not react with the aluminum and thus, generate fewer, if any, particles.

During deposition processes, as opposed to cleaning processes, deposition occurs on the exposed areas of the chamber in the processing volume 108. As the plasma is ignited in the hollow cathode cavities 214 as well as in the processing volume 108, rather than in the area between the showerhead 124 and the backing plate 122, deposition typically does not occur within the area between the showerhead 124 and the backing plate 122 unless the plasma or radicals from the deposition plasma seeps back through the pinch point 212. It is possible that some radicals from the deposition plasma will seep back through the pinch point 212. Thus, the radicals from the cleaning gas plasma can be beneficial in the area between the showerhead 124 and the backing plate 122.

The cleaning gas radicals are introduced into the three possible areas discussed above, namely: between the showerhead 124 and the blocker plate assembly 180; between the blocker plate assembly 180 and the backing plate 122; and between blocker plates 202, 204 of the blocker plate assembly 180. Additional gas may be delivered through the through hole 132 from the gas source 134. The additional gas may comprise the same chemical composition as ignited into a plasma in the remote plasma clean source 182. Alternatively, the gas may comprise an inert gas, such as argon. The additional, non-ignited gas, reduces or eliminates the backflow of the radicals and thus facilitates movement of the radicals through the holes 140 in the showerhead 124. The less backflow of the radicals from the cleaning plasma, the less likely particles are to develop in the area between the backing plate 122 and showerhead 124.

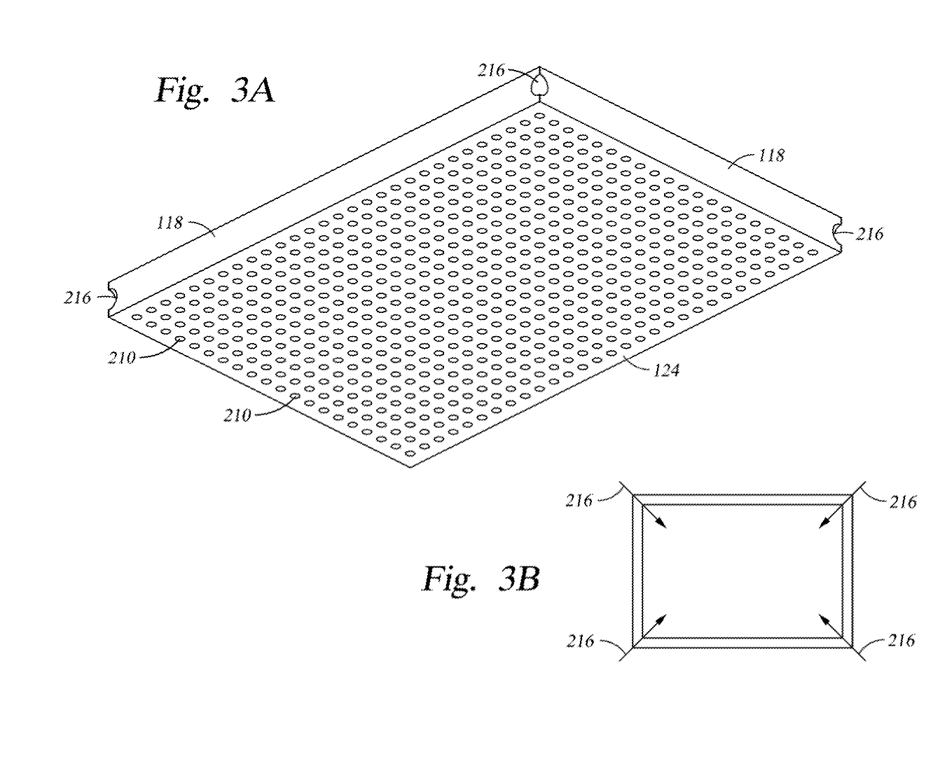

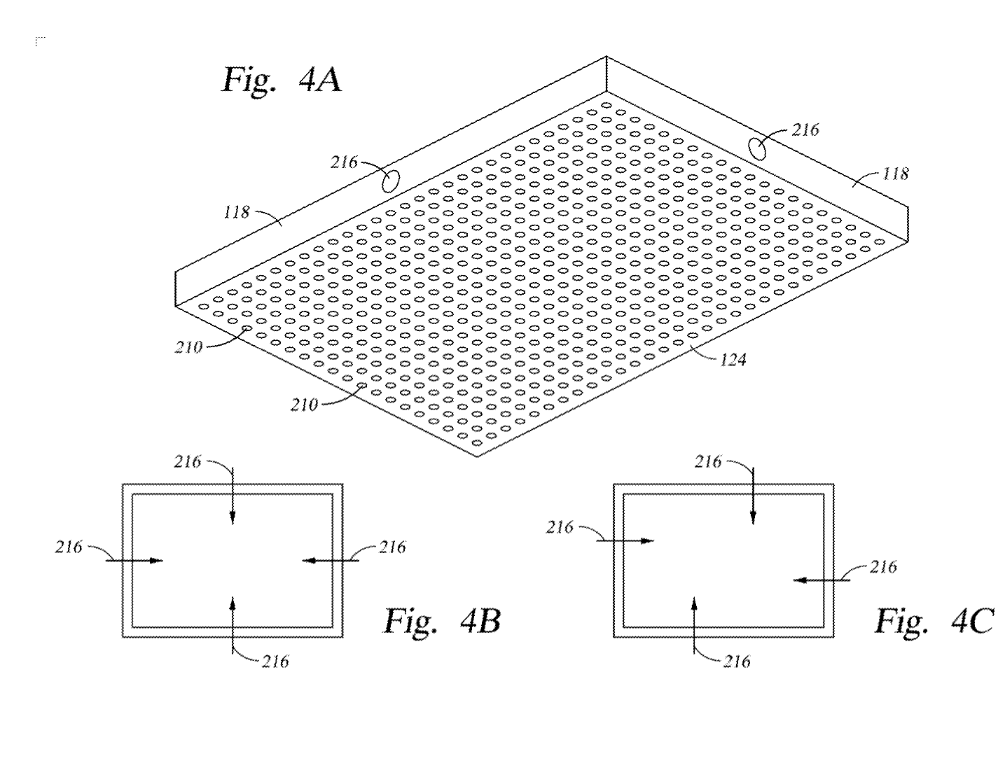

There are several possible locations for the outlets 216. FIGS. 3A-3B and 4A-4C show two possible locations for the outlets 216. FIGS. 3A and 3B are isometric illustrations of outlets 216 from the RPS 182 according to one embodiment. In FIGS. 3A and 3B, the outlets 216 are disposed at the corners of the outer lid 118. In FIG. 3A, the showerhead 124 is exemplified, but it is understood that the outlets 216 are not limited to being in the corner of the outer lid 118 above the showerhead 124. Rather, the outlets 216 may be disposed in the corner of the outer lid 118 between the showerhead 124 and the blocker plate assembly 180; between the blocker plate assembly 180 and the backing plate 122; and between blocker plates 202, 204 of the blocker plate assembly 180.

FIGS. 4A-4C are isometric illustrations of outlets 216 from the remote plasma clean source 182 according to another embodiment. In FIGS. 4A and 4B, the outlets 216 are disposed in the middle of the outer lid 118. In FIG. 4C, the outlets are disposed at locations spaced from the center of the middle of the outer lid 118. Again, as in FIG. 3A, the showerhead 124 is exemplified, but it is to be understood that the outlets are not limited to being in the middle of the outer lid 118 above the showerhead 124. Rather, the outlets 216 may be disposed in the middle of the outer lid 118 between the showerhead 124 and the blocker plate assembly 180; between the blocker plate assembly 180 and the backing plate 122; and between blocker plates 202, 204 of the blocker plate assembly 180.

It is to be understood that while FIGS. 3A-3B and 4A-4C show the outlets 216 to be at the corners and middle of the outer lid 118 respectively, it is contemplated that the outlets 216 may be at both locations (i.e., corners and middle).

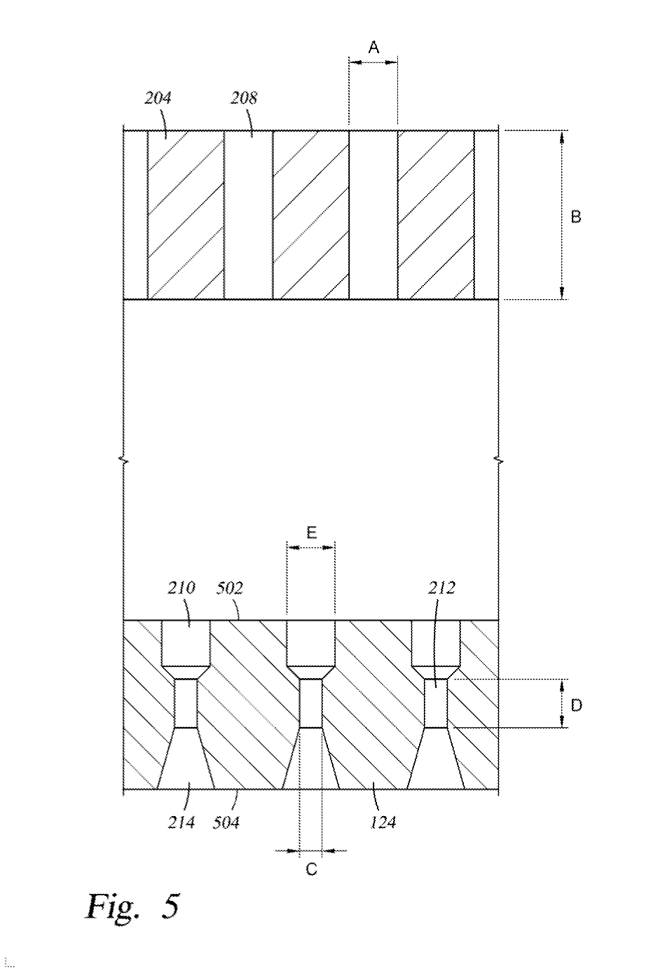

FIG. 5 is a schematic cross-sectional illustration of a blocker plate 204 and showerhead 124 according to one embodiment. In the embodiment shown in FIG. 5, the blocker plate 204 has a gas passage 208 that has a substantially uniform diameter “A” and uniform length “B”. Similarly, the showerhead 124 has a pinch point 212 having a diameter “C” and a length “D”. The diameters of the pinch point and the gas passage 208 affect the flow rate of the gas and/or radicals therethrough. To fabricate the pinch point 212, the showerhead 124 is drilled from one side 502 thereof to form the top bore 210 and a portion of the pinch point 212. Additionally, the showerhead 124 is drilled from the opposite side 504 to form the hollow cathode cavity 214 and the remainder of the pinch point 212. As shown in FIG. 5, the top bore 210 has a diameter “E” that is different than the diameter “C” of the pinch point 212. Additionally, the hollow cathode cavity has a diameter that increases from the pinch point 212 to the opposite side 504. Drilling from opposite sides of the showerhead 124 can be challenging to ensure the pinch point 212 is properly made. A slight miscalculation could easily lead to pinch points 212 of the showerhead 124 being different, which leads to uncertain gas and/or radical flow. Furthermore, the pinch point 212 diameter “C” is small (i.e., between 1 and 5 mils) such that a very small deviation from the desired diameter (e.g., 0.1 mils) could lead to a major flow change. Thus, consistent diameter “C” for the pinch point 212 is quite difficult at small diameters.

The gas passage 208 of the blocker plate 408, on the other hand, has a uniform diameter “A” throughout the entire length “B”. To fabricate the gas passage 208, the blocker plate 204 simply needs to be drilled all the way through from one side. Thus, obtaining a uniform diameter “A” is significantly easier for the blocker plate 204 than for the showerhead 124. Therefore, to ensure the desired flow of processing gas and/or radicals, the conductance of the showerhead 124 can be increased and the conductance of the blocker plate 204 can be decreased. In other words, the diameter “C” can be increased and the diameter “A” can be decreased to achieve the desired flow. Furthermore, the desired flow can be substantially uniform across the showerhead 124. Stated another way, in order to achieve substantially uniform flow through the showerhead 124, the conductance of the showerhead 124 can be increased (i.e., larger diameter “C”) and the conductance of the blocker plate 204 can be decreased (i.e., smaller diameter “A”).

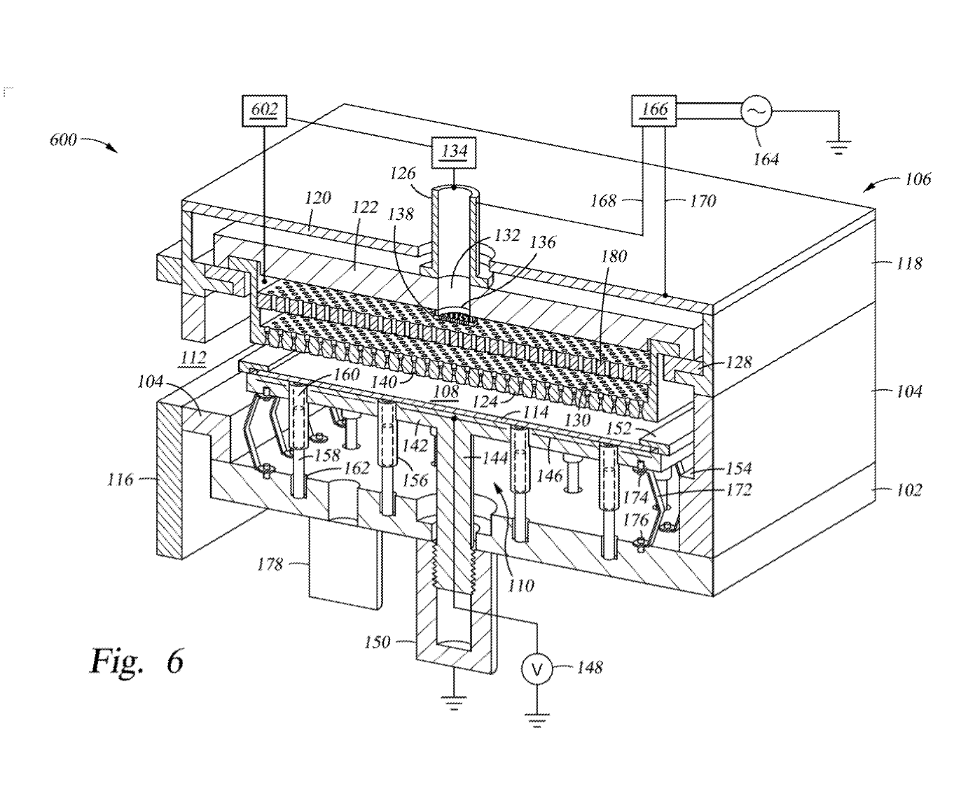

FIG. 6 is a sectional side view of a PECVD chamber 600 according to another embodiment. As shown in FIG. 6, the remote plasma clean source 602 may deliver radicals to both the through hole 132 as well as the location between the showerhead 124 and the backing plate 122 discussed above with regards to FIGS. 2-4.

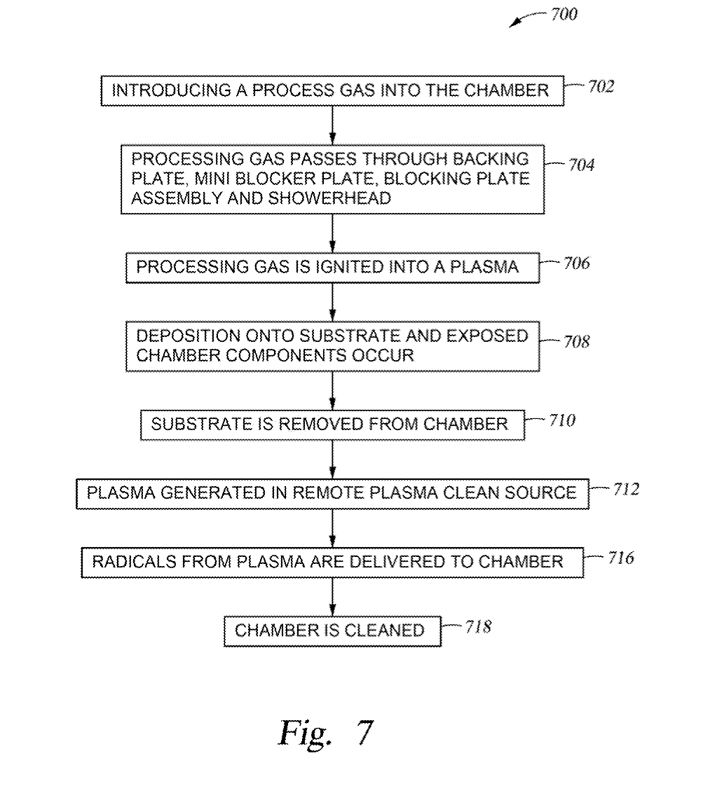

FIG. 7 is a flow chart 700 illustrating the operation of a PECVD chamber. The PECVD process is performed by introducing a processing gas into the chamber 100 (item 702) through the through hole 132 from the gas source 134. The processing gas passes through the backing plate 122, the mini blocker plate assembly 138, the blocking plate assembly 180 and the showerhead 124 (item 704). An RF current is applied to the showerhead 124 to ignite the processing gas into a plasma (item 706). Material is deposited on the substrate and exposed areas of the process volume 108 (item 708). Some of the plasma or radicals form the plasma may seep back through the gas passages 140.

Thereafter, the substrate is removed from the chamber 100 (item 710) and the chamber may be cleaned. To clean the chamber, a plasma may be generated in the remote plasma clean source 182, 602 (item 712) and radicals from the plasma may be delivered to the chamber 100 through the outlets 216 formed in the outer lid 118, and potentially through the through hole 132 (item 714). Simultaneously, additional gas, such as argon, is delivered from the gas source 134 through the through hole 132. The gas and radicals then travel through the gas passages 140 into the process volume 108 to clean the chamber (item 716).

By introducing the radicals from a remote plasma clean source to a location within the chamber between the showerhead and the backing plate, undesired particles are reduced and, potentially eliminated. The gas distribution plate has a flow conductance that is greater than the flow conductance of any blocker plates. Furthermore, during cleaning, argon, nitrogen or a combination thereof is delivered to the chamber to prevent migration of the radicals back through the blocker plate where the radicals may react to form aluminum fluoride.

While the foregoing is directed to embodiments of the present disclosure, other and further embodiments of the disclosure may be devised without departing from the basic scope thereof, and the scope thereof is determined by the claims that follow.

What is claimed is:

1. An apparatus, comprising:
a chamber body;
a gas distribution plate disposed in the chamber body;
a backing plate disposed in the chamber body and spaced from the gas distribution plate;
a blocker plate assembly disposed within chamber body between the gas distribution plate and the backing plate; and
a remote plasma clean source coupled to the chamber body, wherein the remote plasma clean source has at least one outlet in the chamber body and wherein the at least one outlet is disposed between the gas distribution plate and the blocker plate assembly.

2. The apparatus of claim 1, wherein the at least one outlet comprises a plurality of outlets.

3. The apparatus of claim 2, wherein the plurality of outlets are disposed at corners of the chamber body.

4. The apparatus of claim 3, wherein the plurality of outlets are additionally disposed in the middle of chamber walls of the chamber body.

5. The apparatus of claim 2, wherein the plurality of outlets are disposed in the middle of chamber walls of the chamber body.

6. The apparatus of claim 1, wherein the blocker plate has a first flow conductance and the gas distribution plate has a second flow conductance and wherein the second flow conductance is greater than the first flow conductance.

7. An apparatus, comprising:
a chamber body;
a gas distribution plate disposed in the chamber body;
a backing plate disposed in the chamber body and spaced from the gas distribution plate;
a first blocker plate disposed between the gas distribution plate and the backing plate;
a second blocker plate disposed between the first blocker plate and the backing plate; and
a remote plasma clean source coupled to the chamber body, wherein the remote plasma clean source has at least one outlet in the chamber body and wherein the at least outlet is disposed between the first blocker plate and the second blocker plate.

8. The apparatus of claim 7, wherein the at least one outlet comprises a plurality of outlets.

9. The apparatus of claim 8, wherein the plurality of outlets are disposed at corners of the chamber body.

10. The apparatus of claim 9, wherein the plurality of outlets are additionally disposed in the middle of chamber walls of the chamber body.

11. The apparatus of claim 8, wherein the plurality of outlets are disposed in the middle of chamber walls of the chamber body.

12. The apparatus of claim 7, wherein the blocker plate has a first flow conductance and the gas distribution plate has a second flow conductance and wherein the second flow conductance is greater than the first flow conductance.

13. A method of cleaning a processing chamber, comprising:
generating a plasma remote from the processing chamber;
delivering radicals from the plasma to the processing chamber, wherein the radicals are delivered to the processing chamber at a location disposed between a gas distribution plate and a blocker plate;
delivering an inert gas through a backing plate to the processing chamber; and
flowing the radicals and inert gas through the gas distribution plate.

14. The method of claim 13, wherein the radicals are delivered through a plurality of outlets.

15. The method of claim 14, wherein the plurality of outlets are disposed at corners of the processing chamber.

16. The method of claim 14, wherein the plurality of outlets are disposed in the middle of chamber walls of the processing chamber.

17. The method of claim 14, wherein the inert gas comprises argon, nitrogen or a combination thereof and wherein the inert gas prevents migration of the radicals through the blocker plate.

18. A method of cleaning a processing chamber, comprising:
generating a plasma remote from the processing chamber;
delivering radicals from the plasma to the processing chamber, wherein the radicals are delivered to the processing chamber at a location disposed between a first blocker plate and a second blocker plate;
delivering an inert gas through a backing plate to the processing chamber; and
flowing the radicals and inert gas through a gas distribution plate.

19. The method of claim 18, wherein the radicals are delivered through a plurality of outlets.

20. The method of claim 19, wherein the plurality of outlets are disposed at corners of the processing chamber.
